(19) United States
(12) Patent Application Publication
(10) Pub. No.: US 2026/0181770 A1
(43) Pub. Date: Jun. 25, 2026

(54) COMPOSITE SUBSTRATE

(71) Applicant: Murata Manufacturing Co., Ltd., Nagaokakyo-shi (JP)

(72) Inventor: Ryoji TAKAZAWA, Nagaokakyo-shi (JP)

(73) Assignee: Murata Manufacturing Co., Ltd., Nagaokakyo-shi (JP)

(21) Appl. No.: 19/545,032

(22) Filed: Feb. 20, 2026

Related U.S. Application Data
(63) Continuation of application No. PCT/JP2024/020704, filed on Jun. 6, 2024.

(30) Foreign Application Priority Data
Aug. 30, 2023 (JP) 2023-140377

(51) Int. Cl. H05K 1/03; C04B 35/64; H05K 1/16; H05K 3/46

(52) U.S. Cl. CPC H05K 1/036; C04B 35/64; H05K 1/0306; H05K 1/16; H05K 3/4688; H05K 2201/0129; H05K 2201/0141; H05K 2201/0195; H05K 2201/09018; H05K 2201/10098; H05K 2201/10189; H05K 2203/0235

(57) ABSTRACT

A composite substrate includes a resin substrate and a low-temperature fired ceramic bonded to the resin substrate in a thickness direction. The low-temperature fired ceramic is a substantially rectangular cuboid having a first main face, a second main face opposing the first main face, and side faces connecting the first main face and the second main face. The first main face is directly bonded to the resin substrate. Corners between the first main face and the side faces are rounded with a radius R1. Corners between adjacent side faces are rounded with a radius R2. The radius R2 is greater than the radius R1.

### CROSS-REFERENCE TO RELATED APPLICATIONS

This application is a Continuation application of PCT Application No. PCT/JP2024/020704, filed Jun. 6, 2024, which claims the benefit of priority to Japanese Patent Application 2023-140377, filed Aug. 30, 2023. The entire contents of each of the above-referenced applications are incorporated herein by reference.

### TECHNICAL FIELD

The present disclosure relates to composite substrates.

### BACKGROUND ART

In recent years, wireless communication modules employed in wireless communication devices, mainly in mobile devices such as cellphones, have been increasingly required to be miniaturized and reduced in height, as the mounting area within the housing has been progressively reduced due to the advancement of terminal functionality.

For example, Patent Literature 1 discloses an antenna module in which a ceramic dielectric such as LTCC with a patch antenna is bonded to a resin substrate via a solder layer. This antenna module is disadvantageous for miniaturization as it has unfavorable antenna characteristics due to the high resistance of the solder layer and an increased module height resulting from the solder layer thickness.

As a means for solving this problem, for example, Patent Literature 2 discloses a laminated circuit board in which a ceramic multilayer substrate and a resin multilayer substrate are integrated.

### CITATION LIST

### Patent Literature

Patent Literature 1: U.S. Pat. No. 11,670,870
Patent Literature 2: WO 2020-047688 A

### SUMMARY

A composite substrate may include a resin substrate; and a low-temperature fired ceramic bonded to the resin substrate in a thickness direction, wherein the low-temperature fired ceramic is a substantially rectangular cuboid having a first main face, a second main face opposing the first main face, and side faces connecting the first main face and the second main face, the first main face is directly bonded to the resin substrate, corners between the first main face and the side faces are rounded with a radius R1, corners between adjacent side faces are rounded with a radius R2, and the radius R2 is greater than the radius R1.

A composite substrate may include a resin substrate; and a low-temperature fired ceramic bonded to the resin substrate in a thickness direction, wherein the low-temperature fired ceramic is a substantially rectangular cuboid having a first main face, a second main face opposing the first main face, and side faces connecting the first main face and the second main face, the first main face is directly bonded to the resin substrate, corners between the first main face and the side faces are chamfered to define chamfered portions, and a resin forming the resin substrate is raised from the first main face to the side faces, including the chamfered portions, to define a raised portion.

### BRIEF DESCRIPTION OF DRAWINGS

FIG. 1A is a schematic cross-sectional view of an example composite substrate according to a first embodiment.

FIG. 1B is a plan view of the composite substrate in FIG. 1A.

FIG. 2A is a schematic cross-sectional view of another example composite substrate according to the first embodiment.

FIG. 2B is a partially enlarged view of the dotted line portion A of the composite substrate in FIG. 2A.

FIG. 3 is a schematic plan view of an example composite substrate according to a second embodiment.

FIG. 4A is a schematic cross-sectional view of an example composite substrate according to a third embodiment.

FIG. 4B is a plan view of the composite substrate in FIG. 4A.

FIG. 5A is a schematic cross-sectional view of an example composite substrate according to a fourth embodiment.

FIG. 5B is a plan view of the composite substrate in FIG. 5A.

FIG. 6 is a schematic process diagram showing an example step of cutting an LTCC green sheet in a process of producing the composite substrate.

FIG. 7 is a schematic process diagram showing another example step of cutting an LTCC green sheet in the process of producing the composite substrate.

FIG. 8 is a schematic process diagram showing an example step of bonding a low-temperature fired ceramic and a resin substrate in the process of producing the composite substrate.

FIG. 9 is a schematic process diagram showing an example step of cutting the resin substrate in the process of producing the composite substrate.

FIG. 10 is a schematic cross-sectional view of an example antenna module including the composite substrate.

FIG. 11 is a schematic cross-sectional view of another example antenna module including the composite substrate.

FIG. 12 is a partially enlarged view of an antenna module including the composite substrate.

FIG. 13 is a schematic view of an antenna module including the composite substrate, mounted on a motherboard.

FIG. 14 is a schematic view of another antenna module including the composite substrate, mounted on a motherboard.

FIG. 15A is a schematic cross-sectional view of an example composite substrate according to a fifth embodiment.

FIG. 15B is a partially enlarged view of the dotted line portion B of the composite substrate in FIG. 15A.

FIG. 16A is a schematic cross-sectional view of an example antenna module including the composite substrate according to a sixth embodiment.

FIG. 16B is a partially enlarged view of the dotted line portion C of the composite substrate in FIG. 16A.

FIG. 17A is a schematic process diagram showing an example step of producing a low-temperature fired ceramic used for the composite substrate of the sixth embodiment.

FIG. 17B is a schematic process diagram showing an example step of producing the low-temperature fired ceramic used for the composite substrate of the sixth embodiment.

FIG. 17C is a schematic process diagram showing an example step of producing the low-temperature fired ceramic used for the composite substrate of the sixth embodiment.

FIG. 18A is a schematic process diagram showing an example step of producing composite substrates of the fifth embodiment and the sixth embodiment.

FIG. 18B is a schematic process diagram showing an example step of producing the composite substrates of the fifth embodiment and the sixth embodiment.

FIG. 18C is a schematic process diagram showing an example step of producing the composite substrates of the fifth embodiment and the sixth embodiment.

### DESCRIPTION OF EMBODIMENTS

In configurations where a ceramic dielectric (e.g., LTCC) containing an antenna is bonded to a resin substrate via a solder layer, miniaturization is often hindered by unfavorable antenna characteristics caused by high resistance and increased module height resulting from the solder layer thickness. In an attempt to solve the aforementioned problems, structures in which a resin multilayer substrate and a ceramic substrate are integrated have been developed.

However, the inventors have identified that when such a resin multilayer substrate and ceramic substrate are directly bonded via thermal compression-bonding, the resin multilayer substrate may warp after cooling. This warping can lead to delamination at the interface between the ceramic substrate and the resin multilayer substrate, or may cause cracks to occur in the resin substrate.

The present disclosure provides a composite substrate configured to mitigate these issues. Specifically, by configuring a low-temperature fired ceramic bonded to a resin substrate such that corners between the first main face and the side faces are rounded with a radius R1, and corners between adjacent side faces are rounded with a radius R2, where R2 is greater than R1, the stress distribution at the bonding interface is improved. This geometry significantly reduces the occurrences of delamination at the bonding interface and the formation of cracks in the resin substrate.

Hereinafter, the composite substrates of the present disclosure will be described. The present disclosure is not limited to the following configurations, and changes can be appropriately applied thereto within a range not changing the gist of the present disclosure. The present disclosure also includes a combination of two or more of the individual configurations of the present disclosure described below.

The following describes embodiments of the composite substrates of the present disclosure with reference to the drawings.

### First Embodiment to Fourth Embodiment

Composite substrates according to the first embodiment to the fourth embodiment are composite substrates according to one aspect of the composite substrate. The composite substrates each include a resin substrate and a low-temperature fired ceramic bonded to the resin substrate in a thickness direction. The low-temperature fired ceramic is a substantially rectangular cuboid, i.e., except for the rounded corners/edges and manufacturing tolerance, having a first main face, a second main face opposing the first main face, and side faces connecting the first main face and the second main face. The first main face is directly bonded to the resin substrate. Corners between the first main face and the side faces are rounded with a radius R1. Corners between adjacent side faces are rounded with a radius R2. The radius R2 is greater than the radius R1. The radius R1 corresponds to the rounding of the edges along the perimeter of the main face (in a cross-sectional view), whereas the radius R2 corresponds to the rounding of the corners of the ceramic body (in a plan view along the thickness direction).

The composite substrate according to the first embodiment of the present disclosure is described.

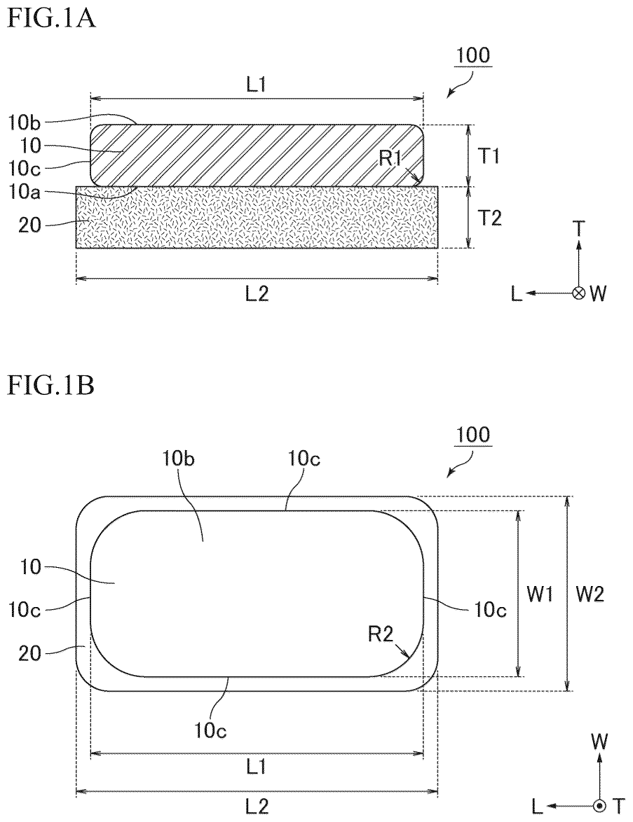

FIG. 1A is a schematic cross-sectional view of an example composite substrate according to the first embodiment.

FIG. 1B is a plan view of the composite substrate in FIG. 1A.

Herein, the length direction, thickness direction, and width direction are defined as directions L, T, and W, respectively, as shown in FIG. 1A and the like. The length direction L, the thickness direction T, and the width direction W are mutually orthogonal. A direction orthogonal to the thickness direction T and including the length direction L and the width direction W is defined as a planar direction (LW planar direction).

A composite substrate 100 includes a low-temperature fired ceramic (low-temperature co-fired ceramic; LTCC) 10 and a resin substrate 20.

As shown in FIG. 1A and FIG. 1B, the low-temperature fired ceramic 10 is a substantially rectangular cuboid having a first main face 10a, a second main face 10b opposing the first main face 10a, and side faces 10c connecting the first main face 10a and the second main face 10b. The low-temperature fired ceramic 10 may have a substantially cubic shape.

As shown in FIG. 1B, the low-temperature fired ceramic 10 has a substantially rectangular shape having a length L1 and a width W1 when viewed in a thickness direction T.

The low-temperature fired ceramic 10 is bonded to the resin substrate 20 in the thickness direction T. The first main face 10a of the low-temperature fired ceramic 10 is directly bonded to the resin substrate 20. As used herein, “directly bonded” refers to a bond formed without a distinct adhesive layer (such as solder or glue) applied between the bulk materials. It encompasses bonding via atomic diffusion, alloy layer formation at the interface, and mechanical anchoring where the resin conforms to surface irregularities of the ceramic.

As shown in FIG. 1A, corners between the first main face 10a and the side faces 10c of the low-temperature fired ceramic 10 are rounded with a radius R1. The entire outer periphery of the first main face 10a of the low-temperature fired ceramic 10 may be rounded with the radius R1 in the thickness direction T.

The low-temperature fired ceramic 10 may have a constant radius R1 as shown in FIG. 1A. The radius R1 may not be constant.

As shown in FIG. 1A, corners between the second main face 10b and the side faces 10c of the low-temperature fired ceramic 10 are also rounded with the radius R1. The entire outer periphery of the second main face 10b of the low-temperature fired ceramic 10 may be rounded with the radius R1 in the thickness direction T. The corners between the second main face 10b and the side faces 10c may be rounded with any radius, e.g., the radius R1.

As shown in FIG. 1B, corners between adjacent side faces 10c of the low-temperature fired ceramic 10 are rounded with a radius R2. The low-temperature fired ceramic 10 is a substantially rectangular cuboid having four side faces 10c, and has four corners rounded with the radius R2.

The low-temperature fired ceramic 10 has a constant radius R2 as shown in FIG. 1B. The radius R2 may not be constant.

In the low-temperature fired ceramic 10, the radius R2 is greater than the radius R1. When the radius R2 is greater than the radius R1, occurrences of delamination at the bonding interface between the low-temperature fired ceramic and the resin substrate and cracks in the resin substrate are reduced.

The radius R1 is not limited, but may be between 0.020 mm and 0.400 mm, inclusive.

The radius R2 is not limited, but may be between 0.500 mm and 1.20 mm, inclusive.

When R1 and R2 are in the above ranges, respectively, occurrences of delamination at the bonding interface between the low-temperature fired ceramic and the resin substrate and cracks in the resin substrate are further reduced. The radius R1 and the radius R2 can each be determined by exposing each corner through cross-sectional polishing and measuring the length by a known method such as using a microscope or metallurgical microscope, for example.

The ratio between the radius R2 and the radius R1 is not limited. For example, the radius R2/the radius R1 may be 1.1 or more and 50 or less.

The resin substrate 20 is a substantially rectangular cuboid having a first main face, a second main face opposing the first main face, and side faces connecting the first main face and the second main face. As shown in FIG. 1B, the resin substrate 20 has a substantially rectangular shape having a length L2 and a width W2 when viewed in the thickness direction T. The length L2 and the width W2 are greater than the length L1 and the width W1 of the low-temperature fired ceramic 10, respectively.

The difference between the lengths L1 and L2 is not limited, but may be 0.1 mm or more and 2.0 mm or less, for example.

The difference between the widths W1 and W2 is not limited, but may be 0.1 mm or more and 2.0 mm or less, for example.

As shown in FIG. 1B, the resin substrate 20 has a rectangular shape with rounded corners when viewed in the thickness direction T. The resin substrate 20 may have unrounded corners, and may be rectangular or square when viewed in the thickness direction T.

In the composite substrate 100, the thickness T1 of the low-temperature fired ceramic 10 and the thickness T2 of the resin substrate 20 are the same. The thicknesses T1 and T2 may differ.

The low-temperature fired ceramic may be formed of a material such as a low-temperature co-fired ceramic (LTCC) material. The low-temperature co-fired ceramic material is a ceramic material that can be sintered at temperatures of 1000° C. or lower and can be co-fired with a low-resistive material such as Au, Ag, or Cu. Specific examples of the low-temperature co-fired ceramic material include glass composite low temperature co-fired ceramic materials obtained by mixing a ceramic powder of alumina, zirconia, magnesia, forsterite, or the like with borosilicate glass; crystallized glass low temperature co-fired ceramic materials containing ZnO—MgO—Al₂O₃—SiO₂ crystallized glass; and non-glass low temperature co-fired ceramic materials containing BaO—Al₂O₃—SiO₂ ceramic powder, Al₂O₃—CaO—SiO₂—MgO—B₂O₃ ceramic powder, or the like.

The low-temperature fired ceramic has a coefficient of thermal expansion in the thickness direction T and a coefficient of thermal expansion in the LW planar direction (also referred to as the planar direction coefficient of thermal expansion), each of which is, for example, 1 ppm/° C. or more and 20 ppm/° C. or less.

The coefficient of thermal expansion is a value measured by thermomechanical analysis (TMA).

The resin forming the resin substrate may be a thermosetting resin or a thermoplastic resin. Examples of the thermosetting resin include a phenol resin, an epoxy resin, a polyester resin, a silicone resin, and a polyimide resin. Examples of the thermoplastic resin include a thermoplastic liquid crystal polymer (LCP), a thermoplastic polyimide resin, a polyether ether ketone resin (PEEK), and a polyphenylene sulfide resin (PPS).

Thermoplastic resins are particularly suitable for forming a raised portion of the resin described below because they regain plasticity when heated. Liquid crystal polymers have lower moisture absorption than other thermoplastic resins, thereby preventing variations in electric characteristics and deterioration in electrical connection reliability.

The resin may have a coefficient of thermal expansion in the thickness direction T of 10 ppm/° C. or more, or 200 ppm/° C. or more. The upper limit of the coefficient of thermal expansion in the thickness direction T is not limited, and may be 300 ppm/° C. or less, for example.

The resin may have a coefficient of thermal expansion in the LW planar direction (also referred to as the planar direction coefficient of thermal expansion) of 5 ppm/° C. or more, or 10 ppm/° C. or more. The upper limit of the LW planar direction coefficient of thermal expansion is not limited, and may be 100 ppm/° C. or less, for example.

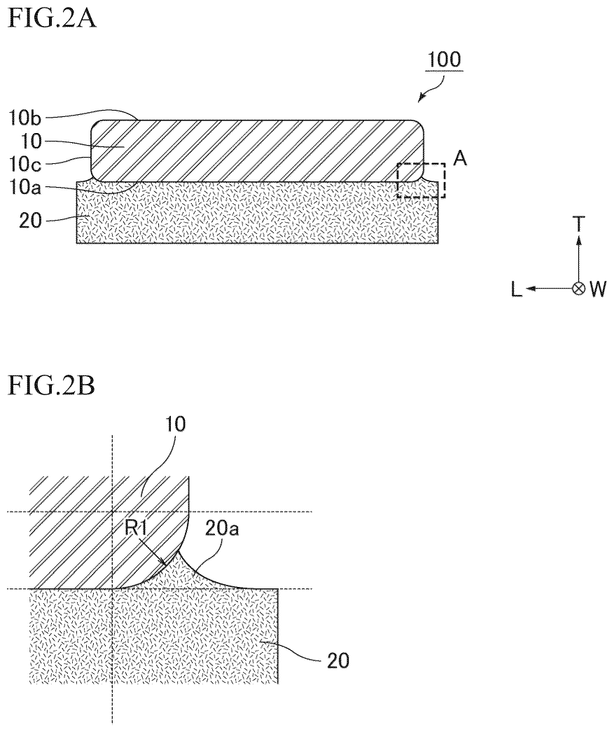

Next, a modified example of the composite substrate according to the first embodiment is described with reference to FIG. 2A and FIG. 2B.

FIG. 2A is a schematic cross-sectional view of another example composite substrate according to the first embodiment. FIG. 2B is a partially enlarged view of the dotted line portion A of the composite substrate in FIG. 2A.

As shown in FIG. 2A and FIG. 2B, the resin forming the resin substrate 20 is raised in the thickness direction T at a bonding end portion where the resin substrate meets the low-temperature fired ceramic 10. A raised portion 20a where the resin is raised extends to intermediate positions of the individual rounded portions between the first main face 10a and the side faces 10c of the low-temperature fired ceramic 10. In other words, the raised portion 20a extends to a position along the curvature of the rounded portions, covering at least a portion of the radius R1 but not necessarily reaching the planar section of the side face 10.

The raised portion 20a is formed along the entire outer periphery of the first main face 10a of the low-temperature fired ceramic 10. The raised portion 20a may form a concave fillet or meniscus shape that tapers from the side face 10c toward the resin substrate 20.

The composite substrate 100 may include the raised portion 20a. When the raised portion 20a is to be formed, the resin for forming the resin substrate 20 may be a thermoplastic resin.

When the raised portion 20a is formed, occurrences of delamination at the bonding interface between the low-temperature fired ceramic and the resin substrate and cracks in the resin substrate can be reduced even when the coefficient of thermal expansion in the thickness direction T of the resin forming the resin substrate 20 is 200 ppm/° C. or more.

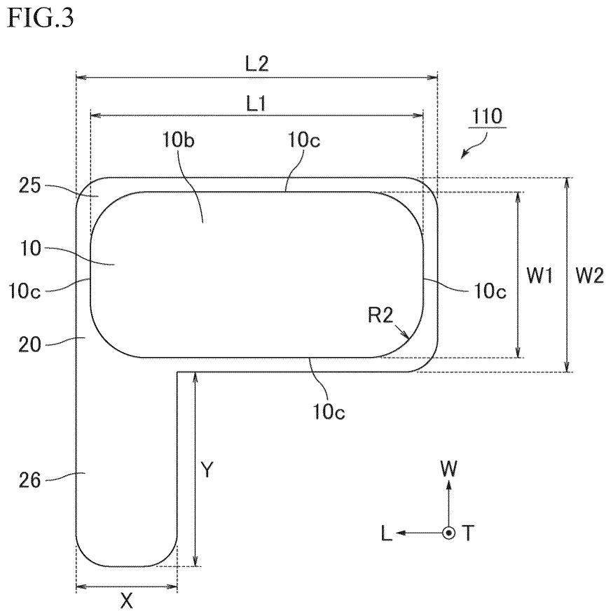

Next, a composite substrate according to the second embodiment is described with reference to FIG. 3. Here, only differences from the composite substrate 100 according to the first embodiment are described, and descriptions of matters common thereto are omitted.

FIG. 3 is a schematic plan view of an example composite substrate according to the second embodiment.

As shown in FIG. 3, the resin substrate 20 of a composite substrate 110 includes a composite portion 25 superimposed with the low-temperature fired ceramic and an extension portion 26 not superimposed with the low-temperature fired ceramic 10.

The composite portion 25 has the same shape as the resin substrate 20 in the first embodiment.

As shown in FIG. 3, the extension portion 26 has a substantially rectangular shape, a part of which protrudes in the width direction W from the composite portion 25. The extension portion 26 has a dimension X in the length direction L and a dimension Y in the width direction W. The dimension X of the extension portion 26 is approximately ⅓ of the length L2 of the resin substrate 20. The dimension X of the extension portion 26 may be approximately ⅕ to ½ of the length L2 of the resin substrate 20. The dimension Y of the extension portion 26 is approximately equal to the width W2 of the resin substrate 20. The dimension Y of the extension portion 26 is not limited as long as it is at least ⅓ of the width W2 of the resin substrate 20.

A part of the extension portion 26 may protrude in the length direction L from the composite portion 25.

The composite substrate 110 has one extension portion 26. However, two or more extension portions 26 may be provided.

As shown in FIG. 3, the composite portion 25 also includes a region not superimposed with the low-temperature fired ceramic 10 around the region superimposed with the low-temperature fired ceramic 10. However, this region not superimposed with the low-temperature fired ceramic 10 does not constitute the extension portion.

Corners of the extension portion 26 are rounded when viewed in the thickness direction T. The corners of the extension portion 26 may not be rounded.

The resin forming the resin substrate 20 of the composite substrate 110 may be raised in the thickness direction T or may not be raised in the thickness direction Tin the bonding end portion to the low-temperature fired ceramic 10.

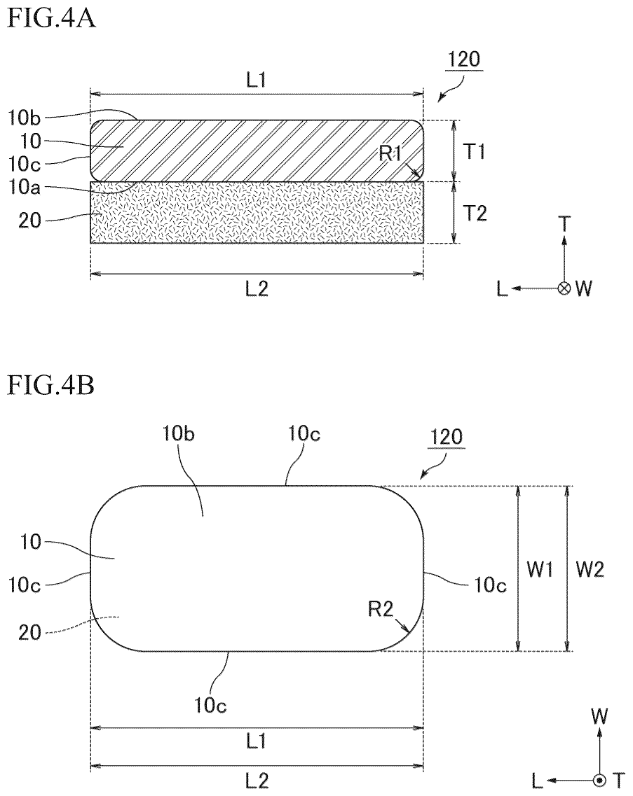

Next, a composite substrate according to the third embodiment is described with reference to FIG. 4A and FIG. 4B. Here, only differences from the composite substrate 100 according to the first embodiment are described, and descriptions of matters common thereto are omitted.

FIG. 4A is a schematic cross-sectional view of an example composite substrate according to the third embodiment. FIG. 4B is a plan view of the composite substrate in FIG. 4A.

In a composite substrate 120, the length L1 and the width W1 of the low-temperature fired ceramic 10 are equal to the length L2 and the width W2 of the resin substrate 20, respectively.

The resin substrate 20 has a rectangular shape with corners rounded with the radius R2 when viewed in the thickness direction T. The resin substrate 20 may have a rectangular shape with unrounded corners when viewed in the thickness direction T.

The resin forming the resin substrate 20 of the composite substrate 120 is not raised in the thickness direction T in the bonding end portion to the low-temperature fired ceramic 10, but may be raised in the thickness direction T.

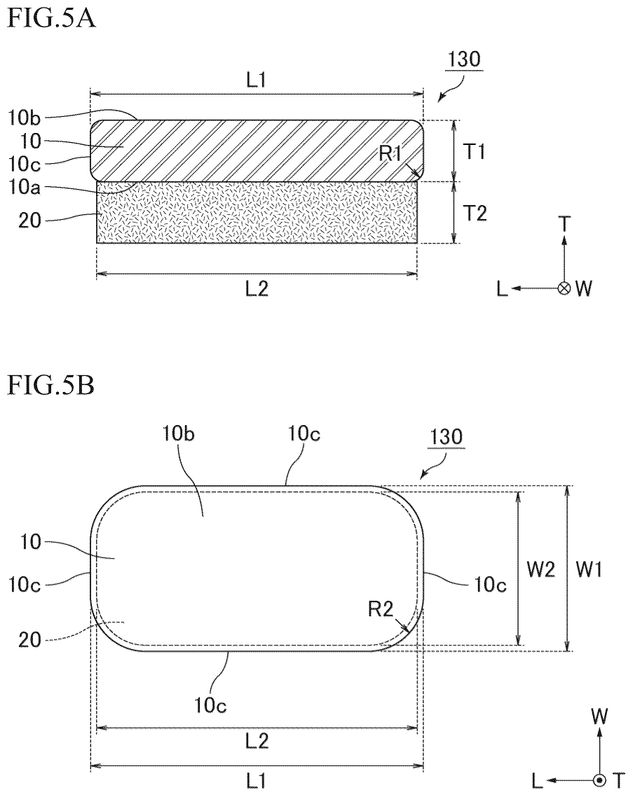

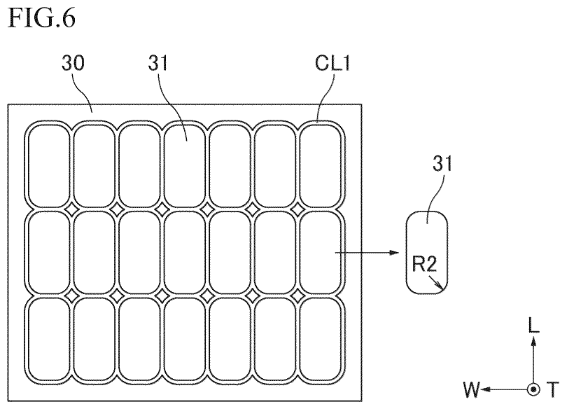

Next, a composite substrate according to the fourth embodiment is described with reference to FIG. 5A and FIG. 5B. Here, only differences from the composite substrate 100 according to the first embodiment are described, and descriptions of matters common thereto are omitted.

FIG. 5A is a schematic cross-sectional view of an example composite substrate according to a fourth embodiment.

FIG. 5B is a plan view of the composite substrate in FIG. 5A.

As shown in FIG. 5A and FIG. 5B, in a composite substrate 130, the length L1 and the width W1 of the low-temperature fired ceramic 10 are greater than the length L2 and the width W2 of the resin substrate 20, respectively.

The resin substrate 20 has a substantially rectangular shape with rounded corners when viewed in the thickness direction T, which is similar to the shape of the low-temperature fired ceramic 10. The resin substrate 20 is smaller than the low-temperature fired ceramic 10 and is centered at the same position as the low-temperature fired ceramic 10 when viewed in the thickness direction T. Thus, the resin substrate 20 does not appear in FIG. 5B.

The resin substrate 20 may have a rectangular shape with unrounded corners when viewed in the thickness direction T.

Next, an example method of producing a composite substrate of the present disclosure is described.

### Step of Preparing LTCC Green Sheets

A low-temperature fired ceramic material is mixed with a binder and a plasticizer in appropriate amounts to prepare a slurry. Examples of the low-temperature fired ceramic material include the materials listed above as the low-temperature co-fired ceramic materials. The binder and the plasticizer can be conventionally known ones.

Subsequently, the slurry is applied to a carrier film to form a sheet to be used as an LTCC green sheet.

The slurry can be applied using a lip coater, a doctor blade, or the like. The slurry may be applied so that the resulting LTCC green sheet has a thickness of between 5 μm and 100 μm, inclusive.

### Step of Laminating LTCC Green Sheets

Subsequently, a plurality of LTCC green sheets are stacked to form an LTCC green sheet stack. The number of sheets to be stacked may appropriately be determined according to the design. The compositions of the plurality of LTCC green sheets may be the same as or different from each other.

Thereafter, the LTCC green sheet stack is placed in a mold and subjected to compression bonding to form an LTCC green sheet laminate. The pressure and temperature may be set as appropriate according to the design.

### Step of Cutting LTCC Green Sheet

FIG. 6 is a schematic process diagram showing an example step of cutting an LTCC green sheet in a process of producing the composite substrate of the present disclosure.

An LTCC green sheet laminate 30 is laser-cut along the cutting lines CL1 as shown in FIG. 6 to produce pre-fired pieces 31 of the low-temperature fired ceramic. At this time, the LTCC green sheet laminate 30 is cut so that, after firing, the corners of adjacent side faces of each low-temperature fired ceramic are rounded with the radius R2.

Subsequently, barrel processing or the like is performed on the pre-fired pieces 31 so that, after firing, the corners between the first main face and the side faces, and the corners between the second main face and the side faces of each low-temperature fired ceramic are rounded with the radius R1. In this manner, low-temperature fired ceramics before firing are obtained.

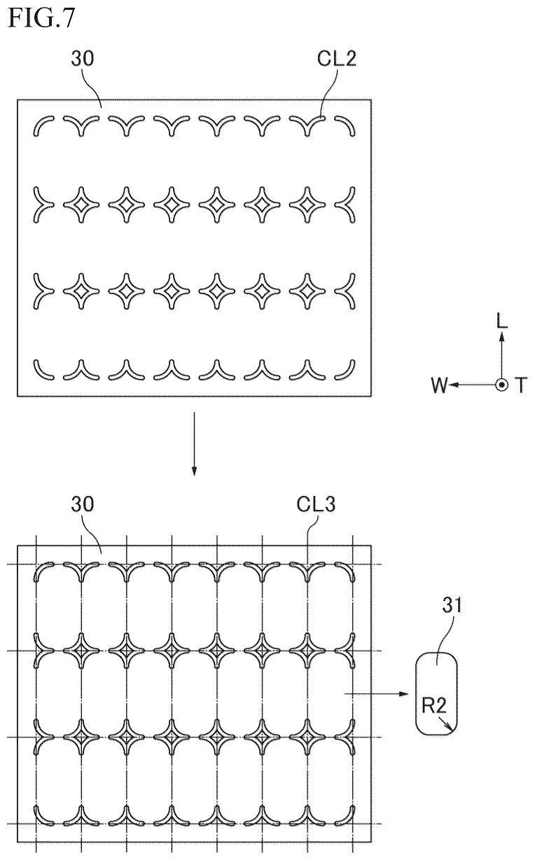

FIG. 7 is a schematic process diagram showing another example step of cutting an LTCC green sheet in the process of producing the composite substrate of the present disclosure.

The following method may be employed as another method for cutting the LTCC green sheet laminate 30 into the pre-fired pieces 31. First, as shown in the upper part of FIG. 7, the LTCC green sheet laminate 30 is laser-cut along the cutting lines CL2. The cutting lines CL2 each have a rounded shape corresponding to a corner between with the radius R2, which corresponds to the corners between adjacent side faces of each low-temperature fired ceramic. Then, as shown in the lower part of FIG. 7, the LTCC green sheet laminate 30 is cut along the straight portions (cutting lines CL3) that will define the side faces. The cutting along the cutting lines CL3 can be performed using a general technique such as dicing. This method enables a reduction in processing time and cost compared to cutting entirely by laser. After the pre-fired pieces 31 are produced, barrel processing or the like is performed in the same manner as described above to obtain low-temperature fired ceramics before firing.

### Step of Firing LTCCs

The low-temperature fired ceramics before firing obtained through the above steps are fired to form low-temperature co-fired ceramics (LTCCs) to be used in the composite substrate of the present disclosure.

The firing can be performed using a firing furnace such as a batch furnace or a belt furnace. The firing conditions are not limited, but the temperature may be 800° C. or higher and 1000° C. or lower.

### Step of Preparing Resin Sheets

Subsequently, a plurality of resin sheets serving as materials for a resin substrate are produced. Since the materials for the resin substrate have already been described above, descriptions thereof are not repeated.

The resin sheets may have a thickness of between 10 μm and 100 μm, inclusive.

### Step of Stacking Resin Sheets

Next, the resin sheets are stacked to form a resin substrate sheet. The number of resin sheets to be stacked may appropriately be determined according to the design. The compositions of the plurality of resin sheets may be the same as or different from each other. According to need, the stack of the resin sheets may be placed in a mold and subjected to compression bonding to form a resin substrate sheet.

### Step of Bonding Low-Temperature Fired Ceramic and Resin Substrate

FIG. 8 is a schematic process diagram showing an example step of bonding a low-temperature fired ceramic and a resin substrate in the process of producing the composite substrate of the present disclosure.

Subsequently, as shown in FIG. 8, fired low-temperature fired ceramics 10 are placed on a resin substrate sheet 40. At this time, the low-temperature fired ceramics are arranged such that the first main faces 10a of the low-temperature fired ceramics come into contact with a surface of the resin substrate sheet 40.

Thereafter, the low-temperature fired ceramics and the resin substrate sheet are pressed together under heat, thereby integrating the low-temperature fired ceramics and the resin substrate sheet.

Although a typical cooled resin substrate sheet warps after bonding, occurrences of delamination between the low-temperature fired ceramics and the resin substrate sheet and cracks in the resin substrate sheet are reduced owing to the corners between the first main face and the side faces of each low-temperature fired ceramic rounded with the radius R1 and the corners between adjacent side faces rounded with the radius R2.

The bonding can be performed by a method including a treatment at, for example, 230° C. or higher and 350° C. or lower and 3 MPa or higher and 20 MPa or lower.

When the resin forming the resin substrate is a thermosetting resin, the low-temperature fired ceramics after firing are arranged on an uncured resin substrate sheet and then pressed together, so that the thermosetting resin is cured to integrate the low-temperature fired ceramics and the resin substrate sheet.

The pressing conditions may include lower temperatures and lower pressures than those for bonding in the method of producing the composite substrates according to the fifth and sixth embodiments described below.

When a raised portion is to be formed on the resin substrate, a thermoplastic resin is used as the material of the resin substrate, and one or both of the heating temperature and the pressing pressure are set high for this bonding step.

### Step of Cutting Resin Substrate

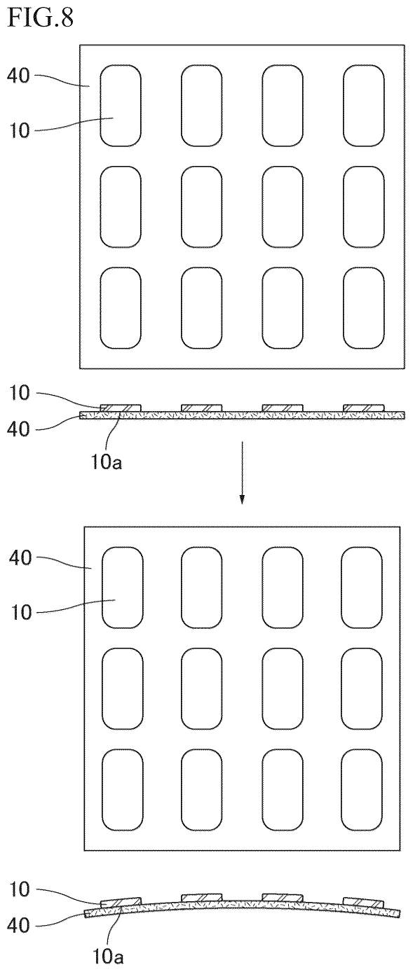

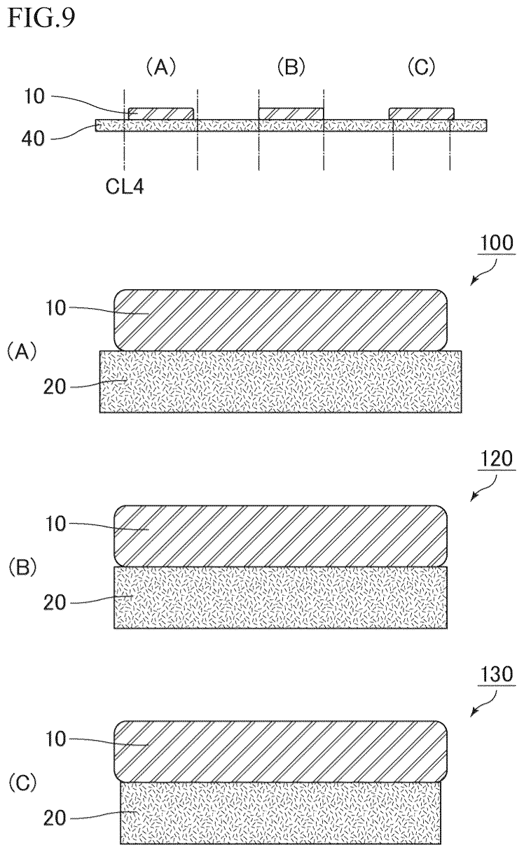

FIG. 9 is a schematic process diagram showing an example step of cutting the resin substrate in the process of producing the composite substrate of the present disclosure.

After the low-temperature fired ceramics 10 and the resin substrate sheet 40 are bonded, the resin substrate sheet 40 is laser-cut along the cutting lines CL4 from the back of the surface that is bonded to the first main faces of the low-temperature fired ceramics 10. In FIG. 9, (A) indicates the composite substrate 100 of the first embodiment, (B) indicates the composite substrate 120 of the third embodiment, and (C) indicates the composite substrate 130 of the fourth embodiment.

The resin substrate conforms to the protrusions and recesses on the surfaces of the low-temperature fired ceramics, and the anchoring effect causes the resin substrate and the low-temperature fired ceramics to come into close contact with each other (also referred to herein as an anchoring interface). When the resin substrate and the low-temperature fired ceramics are brought into direct contact with each other by thermal compression bonding, the resin substrate after cooling may warp to induce occurrences of delamination at the interfaces between the low-temperature fired ceramics and the resin substrate and cracks in the resin substrate.

In the composite substrate of the present disclosure, the corners on the surface of the low-temperature fired ceramic directly bonded to the resin substrate are rounded in the thickness direction and the planar direction, and the rounded portion in the planar direction is greater than the rounded portion in the thickness direction, i.e., the radius R2 is greater than the radius R1. This tends to distribute the stress in the bonding end portion between the low-temperature fired ceramic and the resin substrate, thereby reducing occurrences of delamination at the interface between the low-temperature fired ceramic and the resin substrate and cracks in the resin substrate.

Also, when the resin forming the resin substrate is raised in the thickness direction in the bonding end portion to the low-temperature fired ceramic, the stress is readily distributed even when the coefficient of thermal expansion in the thickness direction of the resin forming the resin substrate is large, thus reducing occurrences of delamination and cracks.

The composite substrate of the present disclosure can serve as an antenna module including a patch antenna, for example.

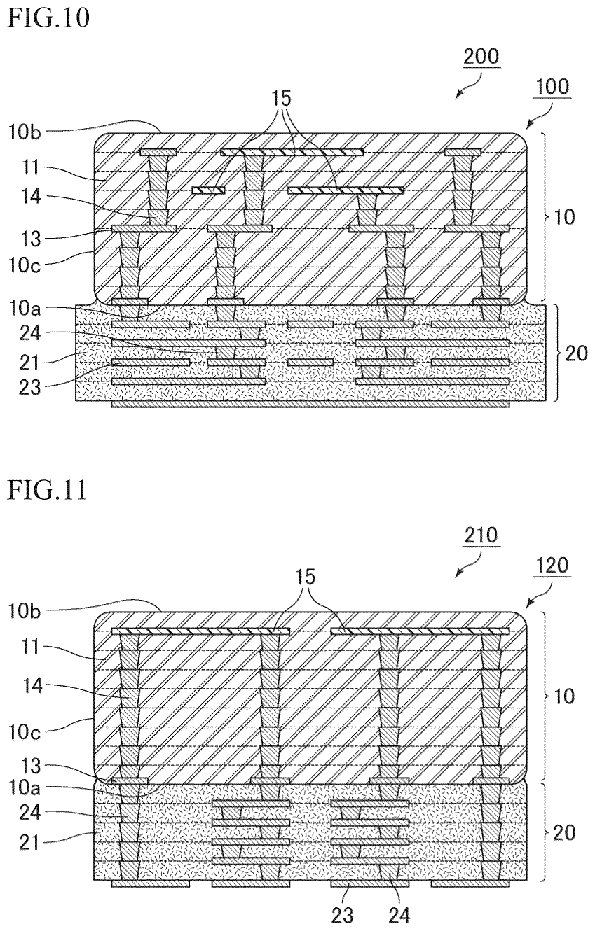

FIG. 10 is a schematic cross-sectional view of an example antenna module including the composite substrate of the present disclosure. As shown in FIG. 10, an antenna module 200 includes the low-temperature fired ceramic 10 including a laminate of a plurality of low-temperature fired ceramic layers 11 (9 layers in FIG. 10), the resin substrate 20 including a laminate of a plurality of resin layers 21 (5 layers in FIG. 10), and a plurality of antennas 15 (3 antennas in FIG. 10) embedded in the low-temperature fired ceramic 10.

In the low-temperature fired ceramic 10, electrode patterns 13, vias 14, and other components are formed.

The electrode patterns 13 are arranged at the interfaces between the low-temperature fired ceramic layers 11 and on the first main face 10a of the low-temperature fired ceramic 10.

The vias 14 are each arranged to penetrate a low-temperature fired ceramic layer 11, and serves to electrically connect between an antenna 15 and an electrode pattern 13 or to electrically connect electrode patterns 13 in different layers. In FIG. 10, there is an antenna 15 not connected to any via 14, but it suffices as long as the antenna 15 is connected to a via 14 somewhere other than the presented cross section.

In the resin substrate 20, electrode patterns 23, vias 24, and other components are formed.

The electrode patterns 23 are arranged at the interfaces between the resin layers 21 and on the main face of the resin substrate 20 not bonded to the low-temperature fired ceramic 10.

The vias 24 are each arranged to penetrate a resin layer 21, and serves to electrically connect between an electrode pattern 13 on the first main face 10a of the low-temperature fired ceramic 10 and an electrode pattern 23 or to electrically connect electrode patterns 23 in different layers.

FIG. 11 is a schematic cross-sectional view of another example antenna module including the composite substrate of the present disclosure. As shown in FIG. 11, an antenna module 210 includes the low-temperature fired ceramic 10 including a laminate of a plurality of the low-temperature fired ceramic layers 11 (9 layers in FIG. 11), the resin substrate 20 including a laminate of a plurality of the resin layers 21 (5 layers in FIG. 11), and a plurality of the antennas 15 (2 antennas in FIG. 11) embedded in the low-temperature fired ceramic 10.

In the antenna module 210, the antennas 15 are each connected to a plurality of (2 in FIG. 11) the vias 14.

The antenna module is produced, for example, following the procedure described below.

### Step of Preparing LTCC Green Sheets

The step of preparing LTCC green sheets can be performed as in the method of producing the composite substrate of the present disclosure.

### Step of Filling Via Holes in LTCC Green Sheets

Next, via holes are formed in each LTCC green sheet. The method of forming via holes is not limited and may be performed using mechanical punching, CO₂ laser processing, UV laser processing, or similar techniques.

Then, the via holes are filled with a conductive paste P1 made of a conductive powder, a plasticizer, and a binder. The conductive powder may include copper (Cu) and an alloy thereof. The conductive powder may include silver (Ag), aluminum (Al), nickel (Ni), stainless steel (SUS), gold (Au), and alloys thereof, for example.

### Step of Forming Electrode Patterns and Antennas on LTCC Green Sheets

Next, on a surface of each LTCC green sheet, patterns of a conductive paste made of a conductive powder, a plasticizer, and a binder are printed. The printing may be performed by screen printing, inkjet printing, gravure printing, or a similar method. The conductive paste may be the same as the conductive paste P1 used to fill the via holes, or may be different from the conductive paste P1.

Also, patch antennas are arranged at predetermined positions on the surface of the LTCC green sheet.

### Step of Laminating LTCC Green Sheets and Step of Cutting LTCC Green Sheets

The steps of laminating LTCC green sheets and cutting the LTCC green sheets can be performed as in the method of producing the composite substrate of the present disclosure.

### Step of Firing LTCCs

The step of firing LTCCs can be performed as in the method of producing the composite substrate of the present disclosure.

This step fires the conductive paste P1 in the via holes to form vias, and also fires the patterns of the conductive paste to form the electrode patterns.

When the conductive paste contains copper (Cu), the firing may be performed in a reducing atmosphere.

### Step of Preparing Resin Sheets

The step of preparing resin sheets can be performed as in the method of producing the composite substrate of the present disclosure.

### Step of Forming Electrode Patterns on Resin Sheets

When the resin substrate is formed of a thermoplastic resin, the main surface of each resin sheet is laminated with metal foil. Thereafter, the metal foil is patterned by etching or a similar process to form an electrode pattern.

Examples of the metal foil include copper (Cu), silver (Ag), aluminum (Al), nickel (Ni), stainless steel (SUS), and alloys thereof.

When the resin substrate is formed of a thermosetting resin, a conductive layer is formed by sequentially performing electroless plating and electrolytic plating on the main surface of each resin substrate sheet. The conductive layer is then patterned to form an electrode pattern.

Examples of plating metals include copper (Cu), silver (Ag), aluminum (Al), nickel (Ni), and alloys thereof.

### Step of Filling Via Holes in Resin Sheets

Next, via holes are formed in each resin sheet. The method of forming the via holes is not limited and may be performed using mechanical punching, CO₂ laser processing, UV laser processing, or similar techniques.

After the via holes are formed, a desmear treatment such as oxygen plasma treatment, corona discharge treatment, or potassium permanganate treatment may be performed.

Subsequently, the via holes are filled with a conductive paste P2, which is a via precursor.

The conductive paste P2 contains a first metal powder and a second metal powder having a higher melting point than the first metal powder. The first metal powder contained in the conductive paste P2 may be powder of Sn or an Sn alloy, while the second metal powder may be powder of a Cu—Ni alloy or a Cu—Mn alloy. Such a conductive paste P2 may be, for example, the conductive paste described in JP 5146627 B.

The conductive paste P2 may contain a flux component. The flux component may be any of various known flux components commonly used in conductive paste materials, and includes resin. Examples of components other than resin include vehicles, solvents, thixotropic agents, and activators.

The filling method is not limited, and techniques such as screen printing and vacuum printing may be employed.

### Step of Laminating Resin Sheets

The step of laminating resin sheets can be performed as in the method of producing the composite substrate of the present disclosure.

### Step of Bonding Low-Temperature Fired Ceramic and Resin Substrate

Subsequently, as in the method of producing the composite substrate of the present disclosure, a step of bonding the low-temperature fired ceramic and the resin substrate is performed. In this step, alignment is performed such that the conductive paste P2 filling the resin substrate comes into contact with the exposed surface of the electrode pattern arranged on the outermost layer of the low-temperature fired ceramic.

In this step, the conductive paste P2 forms vias through melting, followed by solidification.

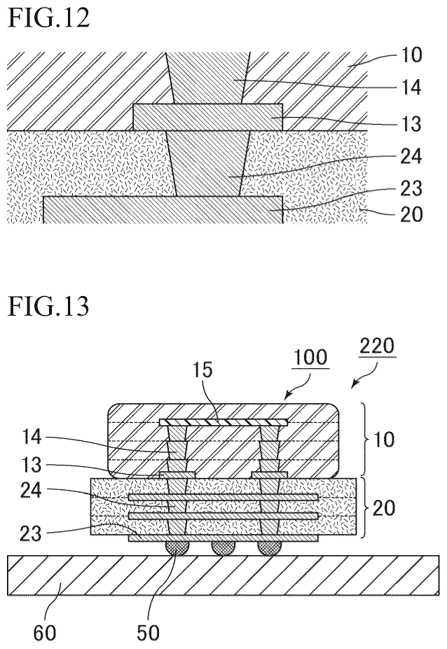

FIG. 12 is a partially enlarged view of an antenna module including the composite substrate of the present disclosure. As shown in FIG. 12, the interface between the low-temperature fired ceramic 10 and the resin substrate 20 in the antenna module includes: (i) a portion where the low-temperature fired ceramic 10 and the resin substrate 20 are bonded; (ii) a portion where the electrode pattern 13 of the low-temperature fired ceramic and the resin substrate 20 are bonded; and (iii) a portion where the electrode pattern 13 of the low-temperature fired ceramic and the via 24 of the resin substrate 20 are bonded.

In the portion (i), as in the composite substrate, the resin substrate conforms to the uneven surface of the low-temperature fired ceramic, thereby generating an anchoring effect, as a result of which the resin substrate and the low-temperature fired ceramic are bonded.

In the portion (ii), an anchoring effect is generated between the resin substrate and the electrode pattern on the surface layer of the low-temperature fired ceramic due to the unevenness of the electrode pattern, and the resin substrate and the low-temperature fired ceramic are bonded.

In the portion (iii), a metal such as Sn or an Sn alloy contained in the via of the resin substrate melts upon heating during bonding and reacts with a metal (e.g., Cu) constituting the electrode pattern on the surface layer of the low-temperature fired ceramic to form an alloy layer, whereby the resin substrate and the low-temperature fired ceramic are bonded and electrically connected.

The antenna module can be mounted on a motherboard as described below, for example.

FIG. 13 is a schematic view of an antenna module including the composite substrate of the present disclosure, mounted on a motherboard. In an antenna module 220, as shown in FIG. 13, the composite substrate 100 according to the first embodiment is used. Solder portions 50 are disposed between the electrode pattern 23 on the main surface of the resin substrate 20 to which the low-temperature fired ceramic is not bonded and a motherboard 60, so that the antenna module 220 and the motherboard 60 are electrically connected.

FIG. 14 is a schematic view of another antenna module including the composite substrate of the present disclosure, mounted on a motherboard. In an antenna module 230, as shown in FIG. 14, the composite substrate 110 according to the second embodiment is used. In the extension portion 26 of the composite substrate 110, the solder portions 50 and a connector 70 are disposed between the electrode pattern 23 on the main surface of the resin substrate 20 to which the low-temperature fired ceramic 10 is not bonded and the motherboard 60, so that the antenna module 230 and the motherboard 60 are electrically connected.

The following describes composite substrates according to another aspect of the composite substrate of the present disclosure.

### Fifth Embodiment and Sixth Embodiment

Composite substrates according to the fifth embodiment and the sixth embodiment are composite substrates according to another aspect of the composite substrate of the present disclosure, each including a resin substrate and a low-temperature fired ceramic bonded to the resin substrate in a thickness direction. The low-temperature fired ceramic is a substantially rectangular cuboid having a first main face, a second main face opposing the first main face, and side faces connecting the first main face and the second main face. The first main face is directly bonded to the resin substrate. Corners between the first main face and the side faces are chamfered to define chamfered portions. A resin forming the resin substrate is raised from the first main face to the side faces, including the chamfered portions, to define a raised portion. Thus, both the chamfered portions and the rounded corners (R1, R2) may provide a stress-distributing geometry.

The composite substrate according to the fifth embodiment is described.

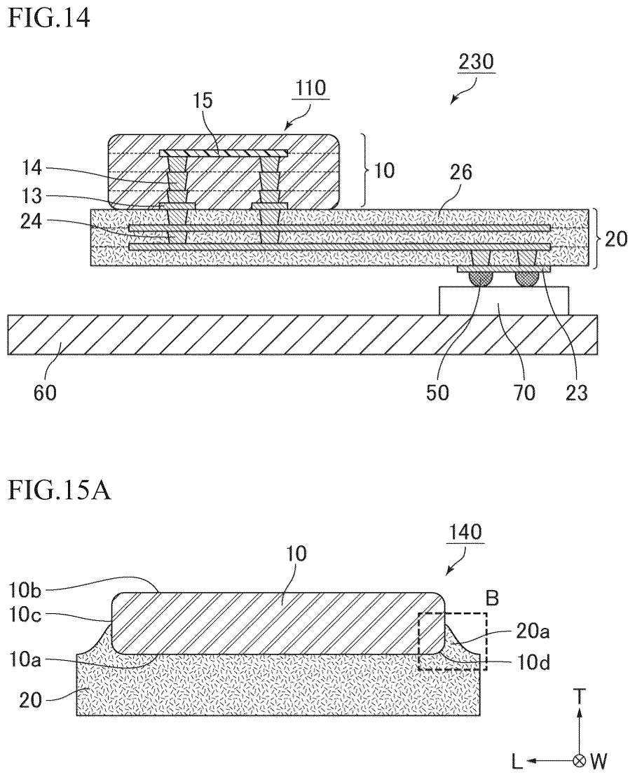

FIG. 15A is a schematic cross-sectional view of an example composite substrate according to the fifth embodiment. FIG. 15B is a partially enlarged view of the dotted line portion B of the composite substrate in FIG. 15A.

A composite substrate 140 includes the low-temperature co-fired ceramic (LTCC) 10 and the resin substrate 20.

The low-temperature fired ceramic and the resin substrate for the composite substrate according to the fifth embodiment may be those similar to the low-temperature fired ceramic and the resin substrate in the composite substrate according to the first embodiment except for the following feature.

The low-temperature fired ceramic 10 is a substantially rectangular cuboid having a first main face 10a, a second main face 10b facing the first main face 10a, and side faces 10c connecting the first main face 10a and the second main face 10b, and the first main face 10a is directly bonded to the resin substrate 20.

The corners between the first main face 10a and the side faces 10c of the low-temperature fired ceramic 10 are chamfered to define chamfered portions 10d.

As shown in FIG. 15B, a “chamfered portion 10d” refers to a region where the surface of the low-temperature fired ceramic 10 is located inward (closer to the low-temperature fired ceramic) relative to an extension line Ea of the first main face 10a and an extension line Ec of the side face 10c when the extension line Ea and the extension line E are drawn and the intersection between the extension line Ea and the extension line Ec is defined as Ep.

The shape of each chamfered portion 10d may be either an R-chamfer or a C-chamfer, and the shape is not limited thereto. FIG. 15B shows an example in which the chamfered portion 10d has an R-chamfer shape.

When the chamfered portion 10d is an R-chamfer, as in the composite substrate according to the first embodiment, the corners are rounded with the radius R1, and the corners between adjacent side faces are rounded with the radius R2. The radius R2 may be greater than the radius R1.

In other words, the composite substrate of the present embodiment may be a composite substrate including: a resin substrate; and a low-temperature fired ceramic bonded to the resin substrate in a thickness direction, wherein the low-temperature fired ceramic is a substantially rectangular cuboid having a first main face, a second main face opposing the first main face, and side faces connecting the first main face and the second main face, the first main face is directly bonded to the resin substrate, corners between the first main face and the side faces are chamfered to define chamfered portions, the corners between the first main face and the side faces are rounded with a radius R1, corners between adjacent side faces are rounded with a radius R2, the radius R2 is greater than the radius R1, and a resin forming the resin substrate is raised from the first main face to the side faces, including the chamfered portions, to define a raised portion.

In the present embodiment, it is not necessary to satisfy the relationship between the radius R2 and the radius R1 defined for the composite substrate according to the first embodiment. Thus, the radius R2 and the radius R1 may be equal to each other or the radius R2 may be less than the radius R1. Additionally, the corners formed between the chamfered portions and the adjacent side faces may not be rounded.

In the composite substrate of the present embodiment, as shown in FIG. 15B, the resin of the resin substrate 20 is raised from the first main face 10a to the side faces 10c, including the chamfered portions 10d, to define the raised portion 20a.

The expression that the raised portion is “raised to the side faces” means that an upper end 20al of the raised portion 20a is positioned above an upper end 10d1 of each chamfered portion 10d, and the upper end 20al of the raised portion 20a is in contact with the side faces 10c.

The position on each side face 10c to which the raised portion 20a is raised is not limited. The upper end 20al of the raised portion 20a may be located below the position corresponding to the half of the thickness of the low-temperature fired ceramic on the side face 10c of the low-temperature fired ceramic 10.

In the composite substrate of the present embodiment, since a chamfered portion is provided between the first main face and the side faces of the low-temperature fired ceramic, stress concentration at the edge portion is less likely to occur when a temperature cycle is applied, which reduces the likelihood of delamination at the bonding interface between the low-temperature fired ceramic and the resin substrate. Furthermore, since a raised portion where the resin is raised from the first main face to the side faces, including the chamfered portions, is provided, the corners of the low-temperature fired ceramic, which tend to serve as initiation points for delamination, are protected by the resin, thereby further reducing the likelihood of delamination at the bonding interface between the low-temperature fired ceramic and the resin substrate.

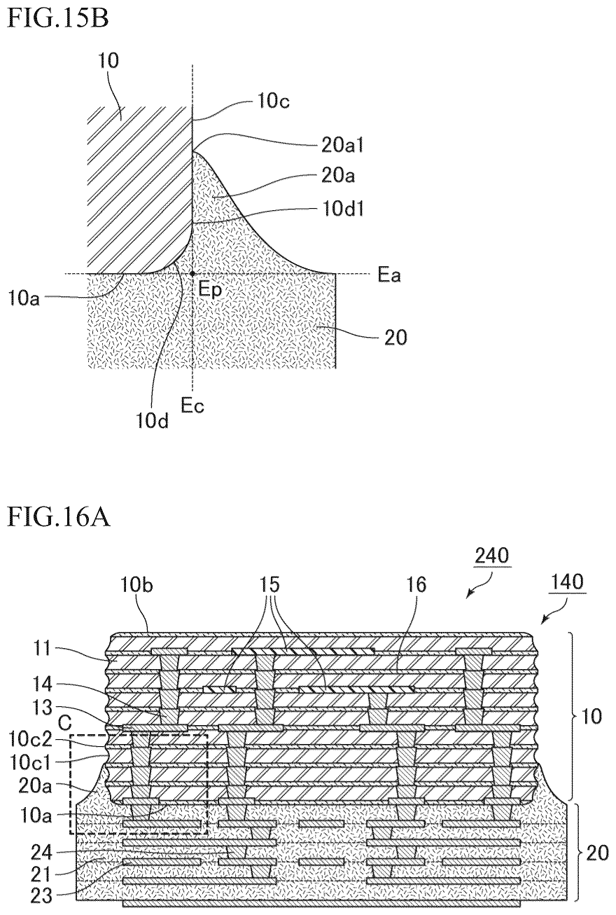

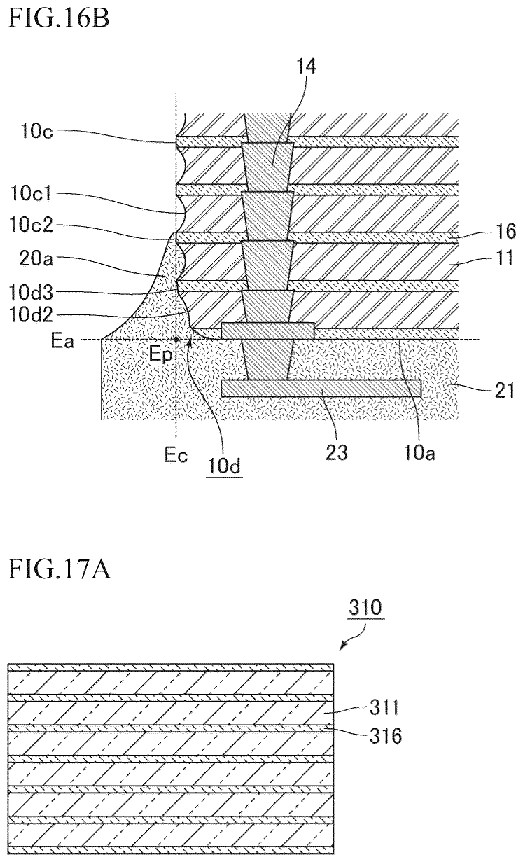

Next, the composite substrate according to the sixth embodiment is described with reference to FIG. 16A and FIG. 16B.

FIG. 16A is a schematic cross-sectional view of an example antenna module including the composite substrate according to the sixth embodiment. FIG. 16B is a partially enlarged view of the dotted line portion C of the composite substrate in FIG. 16A.

An antenna module 240 shown in FIG. 16A includes the composite substrate 140.

The configurations of the antenna module 240 and the composite substrate 140 are basically the same as the configurations of the antenna module 200 and the composite substrate 100 shown in FIG. 10, respectively.

The following describes a low-temperature fired ceramic that includes a constraining layer, with recesses and protrusions on its side faces and chamfered portions.

FIG. 16A shows the detailed layer configuration of the composite substrate 140.

The low-temperature fired ceramic 10 in the composite substrate 140 includes low-temperature fired ceramic layers 11 and constraining layers 16 which are alternately laminated.

The low-temperature fired ceramic layers 11 can be the same as the low-temperature fired ceramic layer 11 described above with reference to FIG. 10.

The constraining layers 16 are each formed by creating a sheet using the doctor blade method from a slurry obtained by adding a resin, a dispersant, a plasticizer, and a solvent to a ceramic powder that does not sinter during the LTCC firing process, followed by mixing. Alumina powder may be used as the ceramic powder used for the constraining layer. The sheet thickness may be, for example, 1 μm or more and 5 μm or less, e.g., 2 μm.

Providing constraining layers allows control of the amount of shrinkage of the LTCC green sheets during the firing step, thereby improving the dimensional accuracy of the low-temperature fired ceramic.

The side faces 10c of the low-temperature fired ceramic 10 include recesses 10c1 and protrusions 10c2.

A recess 10c1 refers to a portion where a side face of a low-temperature fired ceramic layer 11 is curved inward. A protrusion 10c2 refers to a portion where a side face (end portion) of a constraining layer 16 protrudes outward relative to the side faces of the low-temperature fired ceramic layers 11. The constraining layer 16 may include a material that does not shrink (or shrinks less) than the ceramic layer 11 during firing, which results in the protrusion.

The alternating arrangement of the low-temperature fired ceramic layers 11 and the constraining layers 16 results in a side face 10c having a periodic or repeating uneven profile. This profile may be characterized as serrated, wavy, or corrugated, defined by the plurality of alternating recesses 10c1 and protrusions 10c2. While the side face 10c may include only a single recess and protrusion, the side face 10c may include a continuous series of alternating recesses and protrusions corresponding to the lamination of the layers. This repeating structure significantly increases the surface area of the side face 10c available for bonding. Consequently, the resin of the raised portion 20a fills the plurality of recesses 10c1 and conforms to the protrusions 10c2, thereby enhancing the mechanical interlocking (anchoring effect) between the resin substrate 20 and the low-temperature fired ceramic 10 and improving resistance to delamination.

FIG. 16B shows a chamfered portion 10d. Similar to FIG. 15B, FIG. 16B shows an extension line Ea of the first main face 10a, an extension line Ec of the side face 10c, and an intersection Ep between the extension line Ea and the extension line Ec.

At the corner of the low-temperature fired ceramic 10, the surface of the low-temperature fired ceramic 10 is located inward relative to the extension line Ec and the extension line Ea, which indicates that the surface of the low-temperature fired ceramic forms a chamfered portion.

The chamfered portion 10d of the low-temperature fired ceramic 10 also includes recesses 10d2 and protrusions 10d3.

A recess 10d2 refers to a portion where a side face of a low-temperature fired ceramic layer 11 is curved inward. A protrusion 10d3 refers to a portion where a side face (end portion) of a constraining layer 16 protrudes outward relative to the side faces of the low-temperature fired ceramic layers 11.

In the composite substrate of the present embodiment, the side faces and the chamfered portions of the low-temperature fired ceramic have a shape including recesses and protrusions. This configuration increases the bonding strength between the side faces and chamfered portions of the low-temperature fired ceramic and the raised portions of the resin, thereby making delamination at the bonding interface between the low-temperature fired ceramic and the resin substrate less likely to occur.

The composite substrates of the fifth and sixth embodiments can be configured, for example, as antenna modules equipped with a patch antenna.

Furthermore, similar to the composite substrate of the second embodiment shown in FIG. 3, the composite substrates of the fifth and sixth embodiments may have a resin substrate that includes a composite portion superimposed with the low-temperature fired ceramic and an extension portion not superimposed with the low-temperature fired ceramic.

The following describes an example method of producing a low-temperature fired ceramic used for the composite substrate according to the sixth embodiment.

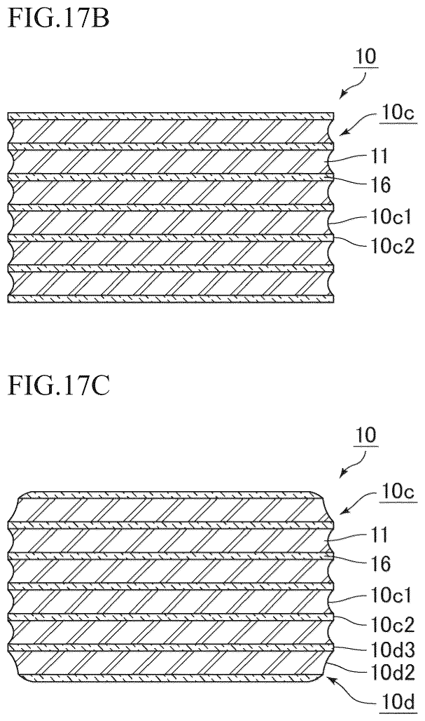

FIG. 17A, FIG. 17B, and FIG. 17C are also schematic process diagrams each showing an example step of producing a low-temperature fired ceramic used for the composite substrate of the sixth embodiment.

As shown in FIG. 17A, LTCC green sheets 311 and constraining layer green sheets 316 are alternately stacked, and compression-bonded in a mold to form a laminate 310.

The LTCC green sheets 311 are each formed by creating a sheet using the doctor blade method from a slurry obtained by mixing a low-temperature co-fired ceramic material, a binder, and a plasticizer in appropriate amounts.

The constraining layer green sheets 316 are each formed by creating a sheet using the doctor blade method from a slurry obtained by adding a resin, a dispersant, a plasticizer, and a solvent to a ceramic powder that does not sinter during the LTCC firing process, followed by mixing.

The resulting laminate is cut into pre-fired pieces, which are then fired to obtain low-temperature fired ceramics 10.

The firing can be performed using a firing furnace such as a batch furnace or a belt furnace. The firing conditions are not limited, but the temperature may be 800° C. or higher and 1000° C. or lower.

FIG. 17B shows a low-temperature fired ceramic 10 obtained by firing.

In the obtained low-temperature fired ceramic 10, the low-temperature fired ceramic layers 11 are portions formed from the LTCC green sheets 311, and the constraining layers 16 are portions formed from the constraining layer green sheets 316.

The LTCC green sheets 311 shrink during firing. However, shrinkage is suppressed on the upper and lower surfaces of each LTCC green sheet 311 which are in contact with individual constraining layer green sheets 316, while shrinkage occurs in the central portion in the thickness direction of the LTCC green sheet 311 which is farther from the constraining layer green sheets 316. As a result, the side faces 10c of the resulting low-temperature fired ceramic layer 11 curve inward to form the recesses 10c1.

Since the constraining layer green sheets 316 do not shrink during firing, the side faces of each constraining layer green sheet 316 form the protrusions 10c2 protruding outward relative to the recesses 10c1 on the respective side faces 10c of the low-temperature fired ceramic layer 11.

When firing is performed after producing pre-fired pieces, the side faces of the resulting low-temperature fired ceramic pieces include recesses and protrusions.

In contrast to the steps above, when a sheet is fired first and then divided into individual pieces, the side faces of the resulting low-temperature fired ceramic pieces remain flat, without recesses or protrusions.

When barrel processing or the like is performed on the low-temperature fired ceramic, chamfered portions where the corners between the first main face and the side faces of the low-temperature fired ceramic are formed after firing.

FIG. 17C shows chamfered portions 10d.

The processing intensity is adjusted to a level such that, after a chamfered portion 10d is formed, the recesses 10d2 and the protrusion 10d3 remain on the chamfered portion 10d.

The following describes an example method of producing the composite substrates according to the fifth embodiment and the sixth embodiment of the present disclosure.

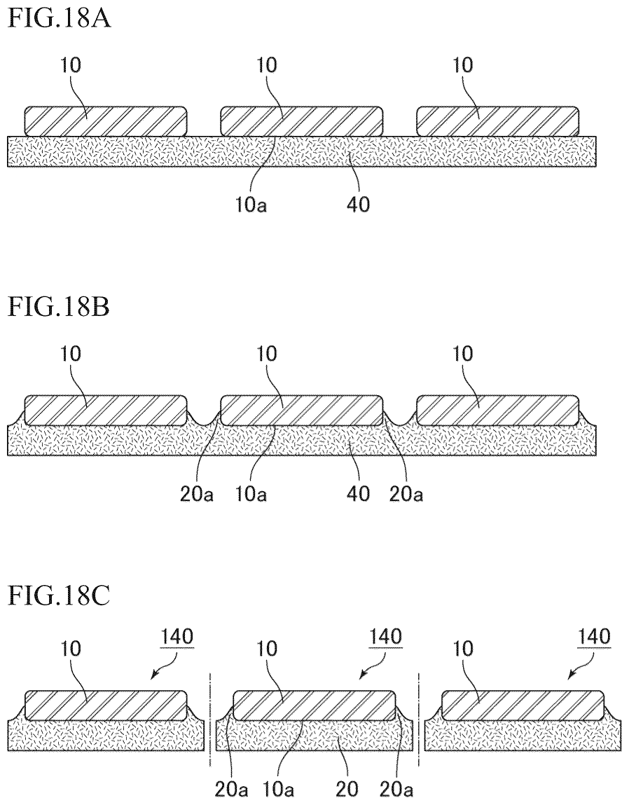

FIG. 18A, FIG. 18B, and FIG. 18C are schematic process diagrams each showing an example step of producing composite substrates of the fifth embodiment and the sixth embodiment.

As shown in FIG. 18A, the low-temperature fired ceramics 10 are disposed such that the first main faces 10a of the low-temperature fired ceramics 10 are in contact with the surface of the resin substrate sheet 40.

Thereafter, as shown in FIG. 18B, the low-temperature fired ceramics and the resin substrate sheet are integrated by pressing the low-temperature fired ceramics and the resin substrate sheet together under heat.

This integration step forms the raised portions 20a.

In this bonding step, for example, a method of treating the workpiece at a temperature of 230° C. or higher and 350° C. or lower and at a pressure of 3 MPa or higher and 20 MPa or lower can be employed.

When a thermoplastic resin is used as the resin substrate sheet to set one or both of the heating temperature and the pressing pressure to a higher level(s) during integration, the height of the raised portions can be increased.

When the heating temperature and the pressing pressure are increased, raised portions are formed where the resin of the resulting resin substrate is raised from the first main faces to the side faces including the chamfered portions.

The pressing conditions may be set to a higher temperature and a higher pressure than those in the bonding step in the method of producing the composite substrates according to the first to fourth embodiments of the present disclosure described above.

Subsequently, as shown in FIG. 18C, after the low-temperature fired ceramics and the resin substrate sheet 40 are bonded, the resin substrate sheet 40 is laser-cut along the cutting lines from the back of the surface bonded to the first main faces 10a of the low-temperature fired ceramics 10. As a result, composite substrates 140 are obtained.

The following contents are disclosed herein.

<1>

A composite substrate, including:
a resin substrate; and
a low-temperature fired ceramic bonded to the resin substrate in a thickness direction,
wherein the low-temperature fired ceramic is a substantially rectangular cuboid having a first main face, a second main face opposing the first main face, and side faces connecting the first main face and the second main face,
the first main face is directly bonded to the resin substrate,
corners between the first main face and the side faces are rounded with a radius R1 to define rounded portions,
corners between adjacent side faces are rounded with a radius R2 to define rounded portions, and
the radius R2 is greater than the radius R1.
   <2>

The composite substrate according to <1>,
wherein a resin forming the resin substrate is a thermoplastic resin.
   <3>

The composite substrate according to <2>,
wherein the resin forming the resin substrate is raised in the thickness direction at a bonding end portion where the resin substrate meets the low-temperature fired ceramic, and
a raised portion where the resin is raised extends to intermediate positions of the individual rounded portions between the first main face and the side faces.
   <4>

The composite substrate according to any one of <1> to <3>,
wherein a resin forming the resin substrate has a coefficient of thermal expansion of 200 ppm/° C. or higher in the thickness direction.
   <5>

The composite substrate according to any one of <1> to <4>,
wherein the resin substrate includes
a composite portion superimposed with the low-temperature fired ceramic, and
an extension portion not superimposed with the low-temperature fired ceramic.
   <6>

The composite substrate according to any one of <1> to <5>,
wherein the radius R1 is between 0.020 mm and 0.400 mm, inclusive, and
the radius R2 is between 0.500 mm and 1.20 mm, inclusive.
   <7>

A composite substrate, including:
a resin substrate; and
a low-temperature fired ceramic bonded to the resin substrate in a thickness direction,
wherein the low-temperature fired ceramic is a substantially rectangular cuboid having a first main face, a second main face opposing the first main face, and side faces connecting the first main face and the second main face,
the first main face is directly bonded to the resin substrate,
corners between the first main face and the side faces are chamfered to define chamfered portions, and
a resin forming the resin substrate is raised from the first main face to the side faces, including the chamfered portions, to define a raised portion.
   <8>

The composite substrate according to <7>,
wherein the side faces and the chamfered portions of the low-temperature fired ceramic have a shape including a recess and a protrusion, and the recess is concave.
   <9>

The composite substrate according to <8>,
wherein the low-temperature fired ceramic is a laminate of a low-temperature fired ceramic layer and a constraining layer, and the low-temperature fired ceramic layer defines the recess and the constraining layer defines the protrusion.

### EXAMPLES

The following describes examples that more specifically disclose the composite substrate of the present disclosure. The present disclosure is not limited to these examples.

### Example 1

### Production of LTCCs

First, a slurry is produced by mixing a ceramic powder, a binder, and a plasticizer in appropriate amounts. The ceramic powder can be any of the ceramic powders described above as a material that constitutes a low-temperature co-fired ceramic material. The binder and the plasticizer may be conventionally known ones. Next, the slurry is applied to carrier films to form sheets, thereby producing LTCC green sheets. The slurry application can be performed using a lip coater or a doctor blade. At this time, the LTCC green sheets may be adjusted to have a thickness of 5 μm or more and 100 μm or less.

In the obtained LTCC green sheets, via holes were formed and filled, and electrode patterns were printed using the procedure described above.

The processed green sheets were stacked in a number according to the design, placed in a mold, and compression-bonded using a press. The obtained compression-bond body was laser-cut into individual pieces having the shape shown in FIG. 1A and FIG. 1B and the dimensions shown in Table 1. Barrel processing was then performed on the individual green sheet pieces to form rounded portions with a radius R1 (0.120 mm) between the first main face and the side faces of each resulting LTCC. After barrel processing, the individual pieces were fired at a temperature of 900° C. or higher and 1000° C. or lower to obtain LTCCs having the desired shape. The coefficient of thermal expansion of the LTCCs was 8.0 ppm/° C. in both the planar direction (LW direction) and the thickness direction (T direction).

### Production of Resin Substrate

Next, the production of the resin substrate will be described. A resin sheet was produced by laminating a liquid crystal polymer (LCP), which is a thermoplastic resin, onto metal foil. Next, the metal foil was patterned by etching to form an electrode pattern on the resin sheet. Subsequently, via holes were formed in the resin sheet by a known method, and the via holes were filled with a conductive paste. A plurality of resin sheets after the conductive paste filling were stacked to produce a resin substrate sheet having a thickness of 0.3 mm. The coefficient of thermal expansion of the liquid crystal polymer was 30 ppm/° C. in both the planar direction (LW direction) and the thickness direction (T direction).

### Lamination of LTCCs and Resin Substrate Sheet

The LTCCs produced above were arranged on the resin substrate sheet as shown in FIG. 8, and pressed together under heat to bond the LTCCs and the resin substrate sheet.

### Formation of Composite Substrates

After the bonded LTCCs and resin substrate sheet were cooled, the resin substrate sheet was laser-cut from the back of the resin substrate sheet to obtain composite substrates having the shape shown in FIG. 1A and FIG. 1B and the dimensions shown in Table 1.

### Example 2

Composite substrates, each including an extension portion, were obtained using the same procedure as in Example 1, except that the radius R1 for the LTCCs was changed, and extension portions having the shape shown in FIG. 3 and the dimensions shown in Table 1 were formed during laser-cutting of the resin sheet laminated with the LTCCs.

### Example 3

Composite substrates were obtained using the same procedure as in Example 1, except that the dimensions of the LTCCs and the resin substrate were changed to the values shown in Table 1, and the resin was a liquid crystal polymer (LCP) having a coefficient of thermal expansion of 40 ppm/° C. in both the planar direction (LW direction) and the thickness direction (T direction).

### Example 4

Composite substrates were obtained using the same procedure as in Example 1, except that the dimensions of the LTCCs and the resin substrate were changed to the values shown in Table 1, the resin was a liquid crystal polymer (LCP) having a coefficient of thermal expansion of 16 ppm/° C. in the planar direction (LW direction) and 250 ppm/° C. in the thickness direction (T direction), and pressing under heat was performed at different temperature and pressure. Raised portions of the resin were formed in the bonding end portions by pressing.

### Example 5

Composite substrates were obtained using the same procedure as in Example 1, except that the dimensions of the LTCCs and the resin substrate were changed to the values shown in Table 1, and the resin was a liquid crystal polymer (LCP) having a coefficient of thermal expansion of 30 ppm/° C. in the planar direction (LW direction) and 40 ppm/° C. in the thickness direction (T direction).

### Example 6

Composite substrates were obtained using the same procedure as in Example 1, except that the dimensions of the LTCCs and the resin substrate were changed to the values shown in Table 1, and the resin was a liquid crystal polymer (LCP) having a coefficient of thermal expansion of 15 ppm/° C. in the planar direction (LW direction) and 270 ppm/° C. in the thickness direction (T direction). Raised portions of the resin were formed in the bonding end portions by pressing.

### Example 7

Composite substrates were obtained using the same procedure as in Example 1, except that the dimensions of the LTCCs and the resin substrate were changed to the values shown in Table 1, and the resin was a liquid crystal polymer (LCP) having a coefficient of thermal expansion of 25 ppm/° C. in the planar direction (LW direction) and 35 ppm/° C. in the thickness direction (T direction).

### Example 8

Composite substrates, each including an extension portion, were obtained using the same procedure as in Example 3, except that the dimensions of the LTCCs and the resin substrate were changed to the values shown in Table 1, and extension portions having the shape shown in FIG. 3 and the dimensions shown in Table 1 were formed during laser-cutting of the resin substrate sheet laminated with the LTCCs.

### Example 9

LTCCs were obtained using the same procedure as in Example 1, except that the dimensions were changed to the values shown in Table 1. Next, a resin substrate sheet with a thickness of 0.90 mm was formed using a polyimide resin, which is a thermosetting resin. To produce the resin substrate sheet, a material obtained by mixing the polyimide resin and an inorganic filler was molded into sheets on carrier films to obtain partially cured polyimide sheets. At this time, the polyimide sheets were heat-treated to adjust their viscosity so as to prevent outflow from the carrier films.

Via holes were formed in the polyimide sheets by laser or the like, and a desmear treatment was performed. Thereafter, the formed vias were filled with a conductive paste. Next, electroless copper plating and electrolytic copper plating were successively performed on the exposed surface of each polyimide sheet to form a conductive layer. This conductive layer was patterned to form an electrode pattern. Thereafter, a predetermined number of the polyimide sheets, from each of which the carrier film had been removed, were stacked to form a resin substrate sheet. Then, as shown in FIG. 8, the LTCCs were arranged on the resin substrate sheet, and the resin substrate sheet was fully cured by pressing under heat, whereby the LTCCs and the polyimide resin were laminated into a composite substrate. After lamination of the LTCCs and the resin substrate sheet, the resin substrate sheet was laser-cut from the back of the resin substrate sheet to obtain composite substrates having the shape shown in FIG. 4A and FIG. 4B and the dimensions shown in Table 1.

### Example 10

Composite substrates were obtained using the same procedure as in Example 1, except that the dimensions of the LTCCs and the resin substrate were changed to the values shown in Table 1, and the resin was a liquid crystal polymer (LCP) having a coefficient of thermal expansion of 15 ppm/° C. in the planar direction (LW direction) and 30 ppm/° C. in the thickness direction (T direction).

### Example 11

Composite substrates were obtained using the same procedure as in Example 7, except that the dimensions of the LTCCs and the resin substrate were changed to the values shown in Table 1.

### Comparative Example 1

Composite substrates were obtained using the same procedure as in Example 1, except that the dimensions of the LTCCs and the resin substrate were changed to the values shown in Table 2.

### Comparative Example 2

Composite substrates were obtained using the same procedure as in Example 5, except that the dimensions of the LTCCs and the resin substrate were changed to the values shown in Table 2.

### Comparative Example 3

Composite substrates, each including an extension portion, were obtained using the same procedure as in Example 3, except that the dimensions of the LTCCs and the resin substrate were changed to the values shown in Table 2, and extension portions having the shape shown in FIG. 3 and the dimensions shown in Table 2 were formed during laser-cutting of the resin substrate sheet laminated with the LTCCs. No rounded portion (R1) in the thickness direction was formed on the LTCCs.

### Comparative Example 4

Composite substrates were obtained using the same procedure as in Example 9, except that no rounded portion was formed on the LTCCs.

TABLE 1

| | LTCC | | | | | | | | | |
|---|---|---|---|---|---|---|---|---|---|---|
| | | | | | | Coefficient of | Coefficient of | | | |
| | | | | | | thermal | thermal | | | |
| | | | | | | expansion | expansion | | | |
| | | | | | | in planar | in thickness | Resin substrate | | |
| | L1 | W1 | T1 | R1 | R2 | direction | direction | L2 | W2 | T2 |
| Example | (mm) | (mm) | (mm) | (mm) | (mm) | (ppm/° C.) | (ppm/° C.) | (mm) | (mm) | (mm) |
| 1 | 22.0 | 4.0 | 0.75 | 0.120 | 0.600 | 8.0 | 8.0 | 22.6 | 4.6 | 0.30 |
| 2 | 22.0 | 4.0 | 0.75 | 0.370 | 0.600 | 8.0 | 8.0 | 22.6 | 4.6 | 0.30 |
| 3 | 11.0 | 7.0 | 0.30 | 0.075 | 0.800 | 8.0 | 8.0 | 11.0 | 7.0 | 1.00 |
| 4 | 11.0 | 7.0 | 0.30 | 0.070 | 0.800 | 8.0 | 8.0 | 11.0 | 7.0 | 1.10 |
| 5 | 11.0 | 7.0 | 0.30 | 0.100 | 1.000 | 8.0 | 8.0 | 11.6 | 7.6 | 0.90 |
| 6 | 12.0 | 6.0 | 0.30 | 0.120 | 1.100 | 8.0 | 8.0 | 12.6 | 6.6 | 0.70 |
| 7 | 13.0 | 7.0 | 0.30 | 0.040 | 0.700 | 8.0 | 8.0 | 12.4 | 6.4 | 1.30 |
| 8 | 10.0 | 8.0 | 0.30 | 0.090 | 0.700 | 8.0 | 8.0 | 10.0 | 8.0 | 0.80 |
| 9 | 8.0 | 6.0 | 0.30 | 0.080 | 0.800 | 8.0 | 8.0 | 8.0 | 6.0 | 0.90 |
| 10 | 12.0 | 6.0 | 0.30 | 0.120 | 0.400 | 8.0 | 8.0 | 12.6 | 6.6 | 0.70 |
| 11 | 13.0 | 7.0 | 0.30 | 0.010 | 0.700 | 8.0 | 8.0 | 12.4 | 6.4 | 1.30 |

| | Resin substrate | | | | | |
|---|---|---|---|---|---|---|
| | | | Coefficient of | Coefficient of | | |
| | | | thermal | thermal | | |
| | Extension | Extension | expansion | expansion | | Resin raised |
| | portion | portion | in planar | in thickness | | portion along |
| | X | Y | direction | direction | Resin | bonding end |
| Example | (mm) | (mm) | (ppm/° C.) | (ppm/° C.) | type | portion |
| 1 | — | — | 30 | 30 | Thermoplastic | Absent |
| 2 | 4.0 | 6.0 | 30 | 30 | Thermoplastic | Absent |
| 3 | — | — | 40 | 40 | Thermoplastic | Absent |
| 4 | — | — | 16 | 250 | Thermoplastic | Present |
| 5 | — | — | 30 | 40 | Thermoplastic | Absent |
| 6 | — | — | 15 | 270 | Thermoplastic | Present |
| 7 | — | — | 25 | 35 | Thermoplastic | Absent |
| 8 | 3.0 | 7.0 | 40 | 40 | Thermoplastic | Absent |
| 9 | — | — | 30 | 30 | Thermosetting | Absent |
| 10 | — | — | 15 | 30 | Thermoplastic | Absent |
| 11 | — | — | 25 | 35 | Thermoplastic | Absent |

TABLE 2

| | LTCC | | | | | | | | | |
|---|---|---|---|---|---|---|---|---|---|---|
| | | | | | | Coefficient of | Coefficient of | | | |
| | | | | | | thermal | thermal | | | |
| | | | | | | expansion | expansion | | | |
| | | | | | | in planar | in thickness | Resin substrate | | |
| Comparative | L1 | W1 | T1 | R1 | R2 | direction | direction | L2 | W2 | T2 |
| Example | (mm) | (mm) | (mm) | (mm) | (mm) | (ppm/° C.) | (ppm/° C.) | (mm) | (mm) | (mm) |
| 1 | 22.0 | 4.0 | 0.75 | 0.120 | 0.120 | 8.0 | 8.0 | 22.6 | 4.6 | 0.3 |
| 2 | 11.0 | 7.0 | 0.30 | 0.100 | 0.100 | 8.0 | 8.0 | 11.6 | 7.6 | 0.9 |
| 3 | 10.0 | 8.0 | 0.30 | — | 0.700 | 8.0 | 8.0 | 10.0 | 8.0 | 0.8 |
| 4 | 8.0 | 6.0 | 0.30 | — | — | 8.0 | 8.0 | 8.0 | 6.0 | 0.9 |

| | Resin substrate | | | | | |
|---|---|---|---|---|---|---|
| | | | Coefficient of | Coefficient of | | |
| | | | thermal | thermal | | |
| | Extension | Extension | expansion | expansion | | Resin raised |
| | portion | portion | in planar | in thickness | | portion along |
| Comparative | X | Y | direction | direction | Resin | bonding end |
| Example | (mm) | (mm) | (ppm/° C.) | (ppm/° C.) | type | portion |
| 1 | — | — | 30 | 30 | Thermoplastic | Absent |
| 2 | — | — | 30 | 40 | Thermoplastic | Absent |
| 3 | 3.0 | 7.0 | 40 | 40 | Thermoplastic | Absent |
| 4 | — | — | 30 | 30 | Thermoplastic | Absent |

The composite substrates obtained as described above were each evaluated for delamination between the LTCC and the resin substrate and for cracks in the resin substrate by visual inspection and observation after cross-sectional polishing. For each example and comparative example, 100 composite substrates were evaluated.

In composite substrates of Examples 1 to 11 in which rounded portions were formed on each LTCC in both the planar direction and the thickness direction and the radius R2 was greater than the radius R1, occurrences of delamination between the LTCC and the resin substrate and cracks in the resin substrate were less than those in the composite substrates of Comparative Examples 1 to 4.

Among Examples 1 to 11, the composite substrates of Examples 1 to 9, in which the radius R1 was between 0.020 mm and 0.400 mm, inclusive and the radius R2 was between 0.500 mm and 1.20 mm, inclusive, exhibited fewer occurrences of delamination between the LTCCs and the resin substrates and cracks in the resin substrates than the composite substrates of Examples 10 and 11.

### REFERENCE SIGNS LIST

10 low-temperature fired ceramic (LTCC)
10a first main face
10b second main face
10c side face
10c1 recess on side face
10c2 protrusion on side face
10d chamfered portion
10d1 upper end of chamfered portion
10d2 recess on chamfered portion
10d3 protrusion on chamfered portion
11 low-temperature fired ceramic layer
13 electrode pattern
14 via
15 antenna
16 constraining layer
20 resin substrate
20a raised portion
20a1 upper end of raised portion
21 resin layer
23 electrode pattern
24 via
25 composite portion
26 extension portion
30 LTCC green sheet laminate
31 pre-fired piece
4 resin substrate sheet
50 solder
60 motherboard
70 connector
100, 110, 120, 130, 140 composite substrate
200, 210, 220, 230, 240 antenna module
310 laminate
311 LTCC green sheet
316 constraining layer green sheet
CL1, CL2, CL3, CL4 cutting line

1. A composite substrate, comprising:
a resin substrate; and
a low-temperature fired ceramic bonded to the resin substrate in a thickness direction,
wherein
the low-temperature fired ceramic is a substantially rectangular cuboid having a first main face, a second main face opposing the first main face, and side faces connecting the first main face and the second main face,
the first main face is directly bonded to the resin substrate,
corners between the first main face and the side faces are rounded with a radius R1 to define a first set of rounded portions,
corners between adjacent side faces are rounded with a radius R2 to define a second set of rounded portions, and
the radius R2 is greater than the radius R1.

2. The composite substrate according to claim 1,
wherein a resin forming the resin substrate is a thermoplastic resin.

3. The composite substrate according to claim 2,
wherein the resin forming the resin substrate is raised in the thickness direction at a bonding end portion where the resin substrate meets the low-temperature fired ceramic, and
a raised portion where the resin is raised extends to intermediate positions of the individual rounded portions of the first set of rounded portions.

4. The composite substrate according to claim 1,
wherein a resin forming the resin substrate has a coefficient of thermal expansion of 200 ppm/° C. or higher in the thickness direction.

5. The composite substrate according to claim 1,
wherein the resin substrate includes
a composite portion superimposed with the low-temperature fired ceramic, and
an extension portion not superimposed with the low-temperature fired ceramic.

6. The composite substrate according to claim 1,
wherein
the radius R1 is between 0.020 mm and 0.400 mm, inclusive, and
the radius R2 is between 0.500 mm and 1.20 mm, inclusive.

7. The composite substrate according to claim 1, wherein the resin substrate includes a liquid crystal polymer.

8. The composite substrate according to claim 1, wherein a thickness of the low-temperature fired ceramic and a thickness of the resin substrate are substantially equal.

9. The composite substrate according to claim 1, wherein the first main face is entirely bonded to the resin substrate.

10. The composite substrate according to claim 1, wherein the side faces of the low-temperature fired ceramic include at least one recess and at least one protrusion.

11. The composite substrate according to claim 10, wherein the low-temperature fired ceramic includes a laminate of a ceramic layer and a constraining layer.

12. The composite substrate according to claim 11, wherein the ceramic layer defines the at least one recess and the constraining layer defines the at least one protrusion.

13. The composite substrate according to claim 1, further comprising a plurality of antennas embedded within the low-temperature fired ceramic.

14. A composite substrate, comprising:
a resin substrate; and
a low-temperature fired ceramic bonded to the resin substrate in a thickness direction,
wherein
the low-temperature fired ceramic is a substantially rectangular cuboid having a first main face, a second main face opposing the first main face, and side faces connecting the first main face and the second main face,
the first main face is directly bonded to the resin substrate,
corners between the first main face and the side faces are chamfered to define chamfered portions, and
the resin substrate includes a raised portion extending from the first main face onto the side faces to cover the chamfered portions.

15. The composite substrate according to claim 14,
wherein the side faces and the chamfered portions of the low-temperature fired ceramic have a shape including a recess and a protrusion, and the recess is concave.

16. The composite substrate according to claim 15,
wherein the low-temperature fired ceramic is a laminate of a low-temperature fired ceramic layer and a constraining layer, and the low-temperature fired ceramic layer defines the recess and the constraining layer defines the protrusion.

17. An antenna module, comprising:
a composite substrate including:
a resin substrate; and a low-temperature fired ceramic bonded to the resin substrate in a thickness direction; and
a plurality of antennas embedded within the low-temperature fired ceramic, wherein
the low-temperature fired ceramic includes a first main face directly bonded to the resin substrate,
corners between the first main face and the side faces rounded with a radius R1, and
corners between adjacent side faces rounded with a radius R2, where R2>R1.

18. The antenna module according to claim 17, further comprising:
an electrode pattern disposed on the first main face of the low-temperature fired ceramic; and
a via penetrating a layer of the resin substrate and electrically connected to the electrode pattern.

19. The antenna module according to claim 17, wherein the resin substrate comprises an extension portion extending beyond a periphery of the low-temperature fired ceramic.

20. The antenna module according to claim 19, further comprising a connector disposed on the extension portion of the resin substrate.
